(19) United States
(12) Patent Application Publication
(10) Pub. No.: US 2020/0274068 A1
(43) Pub. Date: Aug. 27, 2020

(54) VAPOR DEPOSITION MASK BASE MATERIAL, METHOD FOR MANUFACTURING VAPOR DEPOSITION MASK BASE MATERIAL, METHOD FOR MANUFACTURING VAPOR DEPOSITION MASK, AND METHOD FOR MANUFACTURING DISPLAY DEVICE

(71) Applicant: TOPPAN PRINTING CO., LTD., Tokyo (JP)

(72) Inventors: Mikio SHINNO, Tokyo (JP); Masashi KURATA, Tokyo (JP); Naoko MIKAMI, Tokyo (JP)

(21) Appl. No.: 16/870,716

(22) Filed: May 8, 2020

Related U.S. Application Data
(63) Continuation of application No. PCT/JP2018/039966, filed on Oct. 26, 2018.

(30) Foreign Application Priority Data
Apr. 11, 2018 (JP) 2018-076427

(51) Int. Cl. H01L 51/00; C23C 14/04; C25D 1/04; C25D 1/10; C25D 3/56; C25D 5/50; H01L 51/56

(52) U.S. Cl. CPC H01L 51/0011; C23C 14/042; C25D 1/04; H01L 51/56; C25D 3/562; C25D 5/50; H01L 51/001; C25D 1/10

(57) ABSTRACT

A metal foil includes a first surface and a second surface opposite to the first surface. The first surface has a first nickel mass proportion (mass %), which is a percentage of a mass of nickel in a sum of a mass of iron and the mass of nickel at the first surface. The second surface has a second nickel mass proportion (mass %), which is a percentage of a mass of nickel in a sum of a mass of iron and the mass of nickel at the second surface. An absolute value of a difference between the first nickel mass proportion (mass %) and the second nickel mass proportion (mass %) is a mass difference (mass %). A value obtained by dividing the mass difference by a thickness (μm) of the vapor deposition mask substrate is a standard value. The standard value is less than or equal to 0.05 (mass %/μm).

### BACKGROUND

The present disclosure relates to a vapor deposition mask substrate, a method for manufacturing a vapor deposition mask substrate, a method for manufacturing a vapor deposition mask, and a method for manufacturing a display device.

The organic EL elements of an organic EL display device are formed by vapor deposition of an organic material using vapor deposition masks. Vapor deposition masks are made of vapor deposition mask substrates, which are iron-nickel alloy sheets (see Japanese Patent No. 6237972, for example). The iron-nickel alloy sheet is formed by rolling a base material of an iron-nickel alloy into a thin rolled sheet.

Metal foil formed by electroplating has been proposed to be used as the iron-nickel alloy sheet. In manufacturing the metal foil, the metal foil formed by electroplating needs to be annealed to attain a linear expansion coefficient required for the iron-nickel alloy sheet. However, the annealing of metal foil may cause at least one of the four corners of the metal foil to be warped upward relative to the central section. Such warpage of metal foil can reduce the workability in manufacturing of vapor deposition masks, or reduce the accuracy of the shape and position of the through-holes formed in the vapor deposition masks. As such, there is a need for metal foil that is unlikely to be warped upward at the four corners after annealed.

### SUMMARY

It is an objective of the present disclosure to provide a vapor deposition mask substrate, a method for manufacturing a vapor deposition mask substrate, a method for manufacturing a vapor deposition mask, and a method for manufacturing a display device that limit upward warpage at the four corners of the vapor deposition mask substrate, which is metal foil formed by electroplating.

To achieve the foregoing objective, a vapor deposition mask substrate, which is metal foil formed by electroplating, is provided. The metal foil is made of an iron-nickel alloy. The metal foil includes a first surface and a second surface opposite to the first surface. The first surface has a first nickel mass proportion (mass %), which is a percentage of a mass of nickel in a sum of a mass of iron and the mass of nickel at the first surface. The second surface has a second nickel mass proportion (mass %), which is a percentage of a mass of nickel in a sum of a mass of iron and the mass of nickel at the second surface. An absolute value of a difference between the first nickel mass proportion (mass %) and the second nickel mass proportion (mass %) is a mass difference (mass %). A value obtained by dividing the mass difference by a thickness (μm) of the vapor deposition mask substrate is a standard value. The standard value is less than or equal to 0.05 (mass %/μm).

To achieve the foregoing objective, a method for manufacturing a vapor deposition mask substrate, which is metal foil formed by electroplating, is provided. The method includes: forming plating foil by the electroplating; and annealing the plating foil to obtain the metal foil. The metal foil is made of an iron-nickel alloy. The metal foil includes a first surface and a second surface opposite to the first surface. The first surface has a first nickel mass proportion (mass %), which is a percentage of a mass of nickel in a sum of a mass of iron and the mass of nickel at the first surface. The second surface has a second nickel mass proportion (mass %), which is a percentage of a mass of nickel in a sum of a mass of iron and the mass of nickel at the second surface. An absolute value of a difference between the first nickel mass proportion (mass %) and the second nickel mass proportion (mass %) is a mass difference (mass %). A value obtained by dividing the mass difference by a thickness (μm) of the vapor deposition mask substrate is a standard value. The standard value is less than or equal to 0.05 (mass %/μm).

To achieve the foregoing objective, a method for manufacturing a vapor deposition mask by forming a plurality of through-holes in a vapor deposition mask substrate, which is metal foil formed by electroplating, is provided. The method includes: forming plating foil by the electroplating; annealing the plating foil to obtain the metal foil; and forming the through-holes in the metal foil. The metal foil includes a first surface and a second surface opposite to the first surface. The first surface has a first nickel mass proportion (mass %), which is a percentage of a mass of nickel in a sum of a mass of iron and the mass of nickel at the first surface. The second surface has a second nickel mass proportion (mass %), which is a percentage of a mass of nickel in a sum of a mass of iron and the mass of nickel at the second surface. An absolute value of a difference between the first nickel mass proportion (mass %) and the second nickel mass proportion (mass %) is a mass difference (mass %). A value obtained by dividing the mass difference by a thickness (μm) of the vapor deposition mask substrate is a standard value. The standard value is less than or equal to 0.05 (mass %/μm).

To achieve the foregoing objective, a method for manufacturing a display device is provided. The method includes: preparing a vapor deposition mask by the above-described method for manufacturing a vapor deposition mask; and forming a pattern by vapor deposition using the vapor deposition mask.

The standard value, which is the amount of change in the mass proportion of nickel per unit thickness of the vapor deposition mask substrate 10, is less than or equal to 0.05 (mass %/μm), thereby limiting upward warpage at the four corners of the vapor deposition mask substrate relative to the central section.

To achieve the foregoing objective, a vapor deposition mask substrate, which is metal foil formed by electroplating, is provided. The metal foil is made of an iron-nickel alloy. The metal foil includes a first surface and a second surface opposite to the first surface. The first surface has a first nickel mass proportion (mass %), which is a percentage of a mass of nickel in a sum of a mass of iron and the mass of nickel at the first surface. The second surface has a second nickel mass proportion (mass %), which is a percentage of a mass of nickel in a sum of a mass of iron and the mass of nickel at the second surface. An absolute value of a difference between the first nickel mass proportion (mass %) and the second nickel mass proportion (mass %) is a mass difference (mass %). The mass difference is less than or equal to 0.6 (mass %). In this configuration, the mass difference is less than or equal to 0.6 (mass %), thereby limiting upward warpage at the four corners of the vapor deposition mask substrate relative to the central section.

In the above-described vapor deposition mask substrate, the vapor deposition mask substrate may have a thickness of less than or equal to 15 In this configuration, the vapor deposition mask can have holes having a depth of less than or equal to 15 so that the volume of holes in the vapor deposition mask is small. This reduces the amount of vapor deposition material that adheres to the vapor deposition mask when passing through the holes in the vapor deposition mask.

In the above-described vapor deposition mask substrate, each of the first nickel mass proportion and the second nickel mass proportion may be between 35.8 mass % and 42.5 mass % inclusive.

The configuration allows for a smaller difference in linear expansion coefficient between the vapor deposition mask substrate and a glass substrate, and also a smaller difference in linear expansion coefficient between the vapor deposition mask substrate and a polyimide sheet. Consequently, the change in size of the vapor deposition mask caused by thermal expansion will be equivalent to the change in size of a glass substrate and a polyimide sheet caused by thermal expansion. Thus, when the vapor deposition target is a glass substrate or a polyimide sheet, the vapor deposition mask forms the vapor deposition pattern with increased accuracy.

### BRIEF DESCRIPTION OF THE DRAWINGS

FIG. 1 is a perspective view showing the structure of a vapor deposition mask substrate.

FIG. 2 is a plan view showing the structure of a mask device.

FIG. 3 is a partial cross-sectional view showing an example of the structure of a mask portion.

FIG. 4 is a partial cross-sectional view showing another example of the structure of a mask portion.

FIG. 5 is a partial cross-sectional view showing an example of the structure of joining between an edge of a mask portion and a frame portion.

FIG. 6A is a plan view showing an example of the structure of a vapor deposition mask.

FIG. 6B is a cross-sectional view showing the example of the structure of a vapor deposition mask.

FIG. 7 is a process diagram showing a step of forming plating foil by electroplating in a method for manufacturing a vapor deposition mask substrate.

FIG. 8 is a process diagram showing an annealing step in a method for manufacturing a vapor deposition mask substrate.

FIG. 9 is a process diagram showing an etching step for manufacturing a mask portion.

FIG. 10 is a process diagram showing an etching step for manufacturing the mask portion.

FIG. 11 is a process diagram showing an etching step for manufacturing the mask portion.

FIG. 12 is a process diagram showing an etching step for manufacturing the mask portion.

FIG. 13 is a process diagram showing an etching step for manufacturing the mask portion.

FIG. 14 is a process diagram showing an etching step for manufacturing the mask portion.

FIG. 15 is a process diagram showing an example of a step of joining a mask portion to a frame portion in a method for manufacturing a vapor deposition mask.

FIG. 16 is a process diagram showing another example of a step of joining a mask portion to a frame portion in a method for manufacturing a vapor deposition mask.

FIG. 17 is a process diagram showing another example of a step of joining a mask portion to a frame portion in a method for manufacturing a vapor deposition mask.

FIG. 18 is a perspective view for illustrating a method for measuring a curl amount of a vapor deposition mask substrate.

FIG. 19 is a photograph of a vapor deposition mask substrate of Example 5.

FIG. 20 is a photograph of a vapor deposition mask substrate of Example 6.

FIG. 21 is a photograph of a vapor deposition mask substrate of Comparison Example 5.

FIG. 22 is a photograph of a vapor deposition mask substrate of Comparison Example 3.

FIG. 23 is a graph showing the relationship between the standard value and the curl amount.

FIG. 24 is a graph showing the relationship between the mass difference and the curl amount.

### DESCRIPTION OF EXEMPLARY EMBODIMENTS

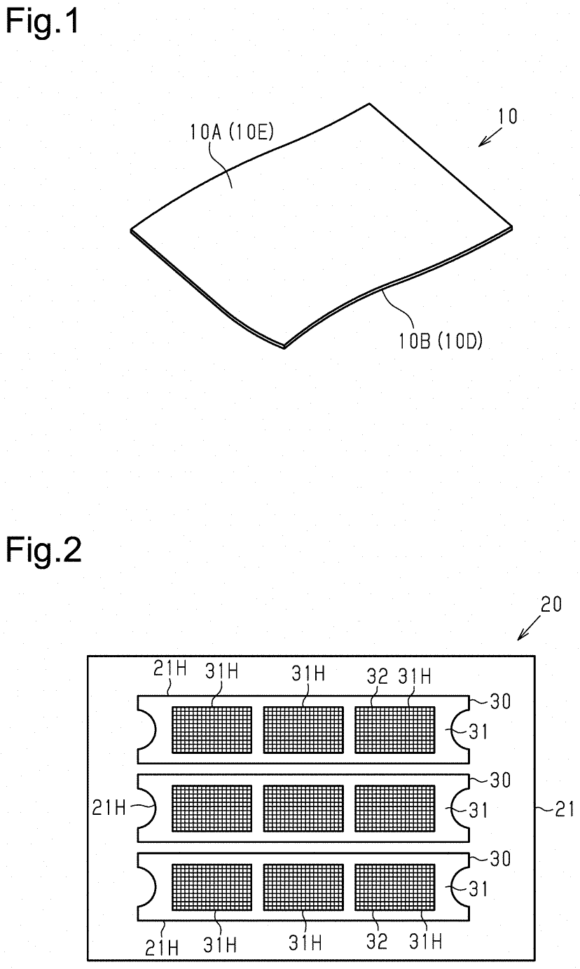

Referring to FIGS. 1 to 24, embodiments of a vapor deposition mask substrate, a method for manufacturing a vapor deposition mask substrate, a method for manufacturing a vapor deposition mask, and a method for manufacturing a display device are described. In the following descriptions, the structure of a vapor deposition mask substrate, the structure of a mask device including vapor deposition masks, a method for manufacturing a vapor deposition mask substrate, a method for manufacturing a vapor deposition mask, a method for manufacturing a display device, and examples are described in this order.

[Structure of Vapor Deposition Mask Substrate]

Referring to FIG. 1, the structure of a vapor deposition mask substrate is now described.

As shown in FIG. 1, a vapor deposition mask substrate 10 is metal foil formed by electroplating. The metal foil is made of an iron-nickel alloy. The vapor deposition mask substrate 10 includes a first surface 10A and a second surface 10B, which is opposite to the first surface 10A. In the vapor deposition mask substrate 10, the absolute value of the difference between the mass proportion (mass %) of nickel (Ni) at the first surface 10A and the mass proportion (mass %) of Ni at the second surface 10B is referred to as a mass difference (mass %) (MD). The value obtained by dividing the mass difference by the thickness (μm) (T) of the vapor deposition mask substrate is referred to as a standard value (MD/T). In the vapor deposition mask substrate 10, the standard value is less than or equal to 0.05 (mass %/μm).

In other words, the first surface 10A has a first nickel mass proportion (mass %), which is the percentage of the mass of nickel in the sum of the mass of iron and the mass of nickel at the first surface 10A. The second surface 10B has a second nickel mass proportion (mass %), which is the percentage of the mass of nickel in the sum of the mass of iron and the mass of nickel at the second surface 10B. The difference between the first nickel mass proportion (mass %) and the second nickel mass proportion (mass %) is referred to as a mass difference (mass %). The value obtained by dividing the mass difference by the thickness (μm) of the vapor deposition mask substrate is referred to as a standard value. The standard value is less than or equal to 0.05 (mass %/μm).

Since the standard value, which is the amount of change in the mass proportion of Ni per unit thickness of the vapor deposition mask substrate 10, is less than or equal to 0.05, the four corners of the vapor deposition mask substrate 10 are unlikely to be warped upward relative to the central section.

The mass proportion of Ni at each surface of the vapor deposition mask substrate 10 is the percentage of the mass of Ni {100×Wni/(Wfe+Wni)} in the sum (Wfe+Wni) of the mass of iron (Wfe) and the mass of Ni (Wni) at each surface. The remainder of the vapor deposition mask substrate 10 other than Ni is iron (Fe). The vapor deposition mask substrate 10 is made of an iron-nickel alloy. The remainder may contain other elements in addition to the main component of Fe. Examples of other elements include Si, C, O and S. The percentage (mass %) of the sum of the mass of Fe and the mass of Ni in the total mass is greater than or equal to 90 mass % at each surface.

The first surface 10A may be an electrode surface 10E, which has been in contact with the electrode for electroplating. The second surface 10B is a deposition surface 10D, which is opposite to the electrode surface 10E. For example, the mass proportion of Ni at the electrode surface 10E may be larger than the mass proportion of Ni at the deposition surface 10D. Alternatively, the mass proportion of Ni at the electrode surface 10E may be smaller than the mass proportion of Ni at the deposition surface 10D. It is desirable that the difference between the mass proportion of Ni at the electrode surface 10E and the mass proportion of Ni at the deposition surface 10D be smaller.

In the present embodiment, the thickness of the vapor deposition mask substrate 10 is less than or equal to 15 μm. Thus, the holes formed in the vapor deposition mask have a depth of less than or equal to 15 μm reducing the volume of the holes in the vapor deposition mask. This reduces the amount of the vapor deposition material that adheres to the vapor deposition mask when passing through the holes in the vapor deposition mask.

In the present embodiment, the mass proportion of Ni at the first surface 10A (the first nickel mass proportion) and the mass proportion of Ni at the second surface 10B (the second nickel mass proportion) are nickel mass proportions. The nickel mass proportions are between 35.8 mass % and 42.5 mass % inclusive. The difference in linear expansion coefficient between the vapor deposition mask substrate 10 and a glass substrate, and the difference in linear expansion coefficient between the vapor deposition mask substrate 10 and a polyimide sheet are thus small. Consequently, the change in size of the vapor deposition mask caused by thermal expansion will be equivalent to the change in size of a glass substrate and a polyimide sheet caused by thermal expansion. Thus, when the vapor deposition target is a glass substrate or a polyimide sheet, the vapor deposition mask forms the vapor deposition pattern with an increased accuracy.

[Structure of Mask Device]

Referring to FIGS. 2 to 6, the structure of a mask device including vapor deposition masks is now described.

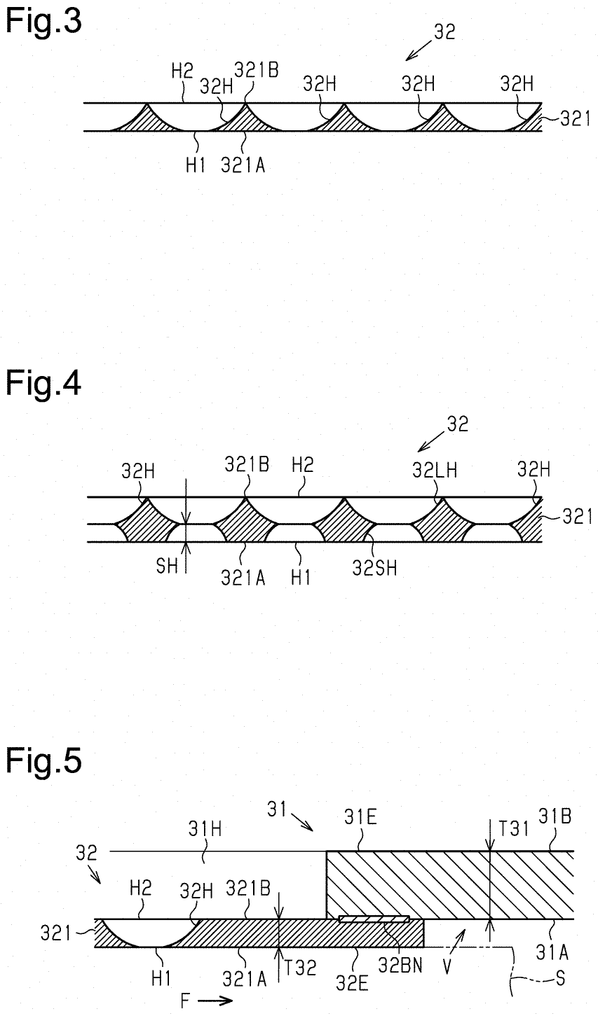

FIG. 2 schematically shows the planar structure of a mask device including vapor deposition masks manufactured using the vapor deposition mask substrate 10. FIG. 3 shows an example of the cross-sectional structure of a mask portion of a vapor deposition mask. FIG. 4 shows another example of the cross-sectional structure of a mask portion of a vapor deposition mask. The quantity of vapor deposition masks in a mask device and the quantity of mask portions in a vapor deposition mask 30 in FIG. 2 are examples of the quantity of vapor deposition masks and the quantity of mask portions.

As shown in FIG. 2, the mask device 20 includes a main frame 21 and three vapor deposition masks 30. The main frame 21 has a rectangular frame shape for supporting the vapor deposition masks 30. The main frame 21 is attached to a vapor deposition apparatus for performing vapor deposition. The main frame 21 includes main frame holes 21H, which extend through the main frame 21 and extend substantially over the entire areas in which the vapor deposition masks 30 are placed.

The vapor deposition masks 30 include frame portions 31, each having the shape of a planar strip, and three mask portions 32 in each frame portion 31. Each frame portion 31, which supports mask portions 32 and has the shape of a planar strip, is attached to the main frame 21. Each vapor deposition mask 30 may be joined to the main frame 21 such that the ends of the vapor deposition mask 30 in the extending direction extend outward beyond the outer edge of the main frame 21.

Each frame portion 31 includes frame holes 31H, which extend through the frame portion 31 and extend substantially over the entire areas in which mask portions 32 are placed. The frame portion 31 has a higher rigidity than the mask portions 32 and is shaped as a frame surrounding the frame holes 31H. The mask portions 32 are separately fixed to the respective frame inner edge sections of the frame portion 31 defining the frame holes 31H. The mask portions 32 may be fixed by welding or adhesion.

As shown in FIG. 3, an example of a mask portion 32 is made of a mask plate 321. The mask plate 321 may be a single planar member made of a vapor deposition mask substrate 10 or a laminate of a single planar member made of a vapor deposition mask substrate 10 and a plastic sheet. FIG. 3 shows the mask plate 321 as a single planar member made of the vapor deposition mask substrate 10.

The mask plate 321 includes a first surface 321A (the lower surface as viewed in FIG. 3) and a second surface 321B (the upper surface as viewed in FIG. 3), which is opposite to the first surface 321A. The first surface 321A faces the vapor deposition target, such as a glass substrate, when the mask device 20 is attached to a vapor deposition apparatus. The second surface 321B faces the vapor deposition source of the vapor deposition apparatus. The mask portion 32 includes holes 32H extending through the mask plate 321. The wall surface defining each hole 32H is inclined with respect to the thickness direction of the mask plate 321 in a cross-sectional view. In a cross-sectional view, the wall surface defining each hole 32H may have a semicircular shape protruding outward of the hole 32H as shown in FIG. 3, or a complex curved shape having multiple bend points.

The mask plate 321 has a thickness of less than or equal to 15 μm. The thickness of the mask plate 321 that is less than or equal to 15 μm allows the holes 32H formed in the mask plate 321 to have a depth of less than or equal to 15 μm. This thin mask plate 321 allows the wall surfaces defining the holes 32H to have small areas, thereby reducing the volume of vapor deposition material adhering to the wall surfaces defining the holes 32H.

The second surface 321B includes second openings H2, which are openings of the holes 32H. The first surface 321A includes first openings H1, which are openings of the holes 32H. The second openings H2 are larger than the first openings H1 in a plan view. Each hole 32H is a passage for the vapor deposition material sublimated from the vapor deposition source. The vapor deposition material sublimated from the vapor deposition source moves from the second openings H2 to the first openings H1. The second openings H2 that are larger than the first openings H1 increase the amount of vapor deposition material entering the holes 32H through the second openings H2. The area of each hole 32H in a cross-section taken along the first surface 321A may increase monotonically from the first opening H1 toward the second opening H2, or may be substantially uniform in a section between the first opening H1 and the second opening H2.

As shown in FIG. 4, another example of a mask portion 32 includes holes 32H extending through the mask plate 321. The second openings H2 are larger than the first openings H1 in a plan view. Each hole 32H consists of a large hole 32LH, which includes a second opening H2, and a small hole 32SH, which includes a first opening H1. The large hole 32LH has a cross-sectional area that monotonically decreases from the second opening H2 toward the first surface 321A. The small hole 32SH has a cross-sectional area that monotonically decreases from the first opening H1 toward the second surface 321B. The section of the wall surface defining each hole 32H where the large hole 32LH meets the small hole 32SH at a middle section in the thickness direction of the mask plate 321 projects inward of the hole 32H. The distance between the first surface 321A and the protruding section of the wall surface defining the hole 32H is a step height SH.

The example of cross-sectional structure shown in FIG. 3 has zero step height SH. To increase the amount of vapor deposition material reaching the first openings H1, the step height SH is preferably zero. In order for a mask portion 32 to have zero step height SH, the mask plate 321 should be thin enough so that wet etching from only one side of the vapor deposition mask substrate 10 achieves formation of holes 32H. For example, the mask plate 321 may have a thickness of less than or equal to 15 μm.

FIG. 5 shows an example of the cross-sectional structure of joining between a mask portion 32 and a frame portion 31. FIG. 5 shows the cross-sectional structure of the joining between a mask portion 32 and a frame portion 31 described above with respect to FIG. 3.

In the example shown in FIG. 5, the outer edge section 32E of a mask plate 321 is a region that is free of holes 32H. The part of the second surface 321B of the mask plate 321 included in the outer edge section 32E of the mask plate 321 is joined to the frame portion 31. The frame portion 31 includes inner edge sections 31E defining frame holes 31H. Each inner edge section 31E includes a joining surface 31A (the lower surface in FIG. 5), which faces the mask plate 321, and a non-joining surface 31B (the upper surface in FIG. 5), which is opposite to the joining surface 31A.

The thickness T31 of the inner edge section 31E, that is, the distance between the joining surface 31A and the non-joining surface 31B is sufficiently larger than the thickness T32 of the mask plate 321, allowing the frame portion 31 to have a higher rigidity than the mask plate 321. In particular, the frame portion 31 has a high rigidity that limits sagging of the inner edge section 31E by its own weight and displacement of the inner edge section 31E toward the mask portion 32. The joining surface 31A of the inner edge section 31E includes a joining section 32BN, which is joined to the second surface 321B.

The joining section 32BN extends continuously or intermittently along substantially the entire circumference of the inner edge section 31E. The joining section 32BN may be a welding mark formed by welding the joining surface 31A to the second surface 321B, or a joining layer joining the joining surface 31A to the second surface 321B. When the joining surface 31A of the inner edge section 31E is joined to the second surface 321B of the mask plate 321, the frame portion 31 applies stress F to the mask plate 321 that pulls the mask plate 321 outward, in other words, in the direction that pulls the ends of the mask plate 321 away from each other.

The main frame 21 also applies stress to the frame portion 31 that pulls the frame portion 31 outward. This stress corresponds to the stress F applied to the mask plate 321. Accordingly, the vapor deposition mask 30 removed from the main frame 21 is released from the stress caused by the joining between the main frame 21 and the frame portion 31, and the stress F applied to the mask plate 321 is relaxed. The position of the joining section 32BN in the joining surface 31A is preferably set such that the stress F isotropically acts on the mask plate 321. Such a position may be selected according to the shape of the mask plate 321 and the shape of the frame holes 31H.

The joining surface 31A is a plane including the joining section 32BN and extends outward of the mask plate 321 from the outer edge section 32E of the second surface 321B. In other words, the inner edge section 31E has a planar structure that virtually extends the second surface 321B outward, so that the inner edge section 31E extends from the outer edge section 32E of the second surface 321B toward the outside of the mask plate 321. Accordingly, in the area in which the joining surface 31A extends, a space V, which corresponds to the thickness of the mask plate 321, is likely to form around the mask plate 321. This limits physical interference between the vapor deposition target S and the frame portion 31 around the mask plate 321.

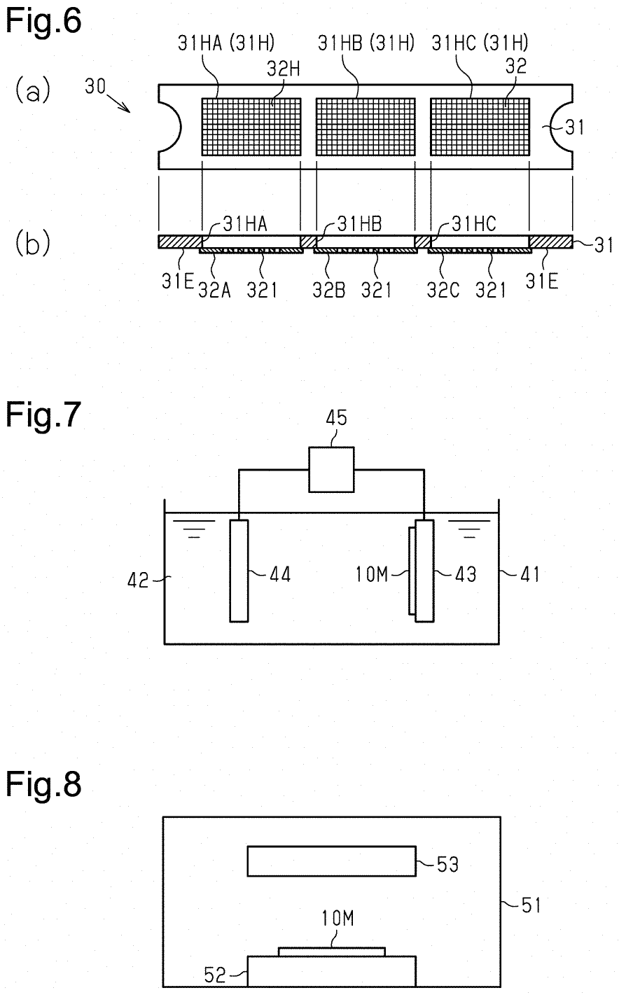

FIGS. 6A and 6B show an example of the relationship between the quantity of holes 32H in a vapor deposition mask 30 and the quantity of holes 32H in a mask portion 32.

FIG. 6A shows an example in which the frame portion 31 includes three frame holes 31H. The three frame holes 31H include a first frame hole 31HA, a second frame hole 31HB, and a third frame hole 31HC. As shown in the example of FIG. 6B, the vapor deposition mask 30 includes one mask portion 32 for each frame hole 31H. The three mask portions 32 include a first mask portion 32A, a second mask portion 32B, and a third mask portion 32C. The inner edge section 31E defining the first frame hole 31HA is joined to the first mask portion 32A. The inner edge section 31E defining the second frame hole 31HB is joined to the second mask portion 32B. The inner edge section 31E defining the third frame hole 31HC is joined to the third mask portion 32C.

The vapor deposition mask 30 is used repeatedly for multiple vapor deposition targets. Thus, the position and structure of the holes 32H in the vapor deposition mask 30 need to be highly accurate. When the position and structure of the holes 32H fail to have the desirable accuracy, the mask portions 32 may require replacement when manufacturing or repairing the vapor deposition mask 30.

When only one of the mask portions 32 needs to be replaced, for example, the structure in which the quantity of holes 32H required in one frame portion 31 is divided into three mask portions 32 as shown in FIGS. 6A and 6B only requires the replacement of one of the three mask portions 32. In other words, the two of the three mask portions 32 continue to be used. Thus, the structure in which the mask portions 32 are separately joined to the respective frame holes 31H reduces the consumption of various materials associated with the manufacturing and repair of the vapor deposition mask 30. In addition, a thinner mask plate 321 and smaller holes 32H tend to reduce the yield of the mask portion 32 and increase the need for replacement of the mask portion 32. Thus, the structure in which each frame hole 31H has one mask portion 32 is particularly suitable for a vapor deposition mask 30 that requires high resolution.

The position and structure of the holes 32H are preferably determined while the stress F is applied, that is, while the mask portions 32 are joined to the frame portion 31. In this respect, the joining section 32BN preferably extends partly and intermittently along the inner edge section 31E so that the mask portion 32 is replaceable.

[Method for Manufacturing Vapor Deposition Mask Substrate]

Referring to FIGS. 7 and 8, a method for manufacturing the vapor deposition mask substrate 10 is now described. The method for manufacturing the vapor deposition mask substrate 10 includes forming plating foil by electroplating, and annealing the plating foil to obtain metal foil. The method for manufacturing the vapor deposition mask substrate 10 of the present embodiment is now described in detail.

FIG. 7 schematically shows a step of forming plating foil by electroplating.

As shown in FIG. 7, to form plating foil by electroplating, a cathode 43 and an anode 44 are arranged in an electrolytic chamber 41 filled with an electrolytic bath 42. A power source 45 connected to the cathode 43 and the anode 44 creates a potential difference between the cathode 43 and the anode 44. This forms plating foil 10M on the surface of the cathode 43. That is, in the plating foil 10M, the surface in contact with the cathode 43 corresponds to the electrode surface 10E of the vapor deposition mask substrate 10, and the surface facing away from the cathode 43 corresponds to the deposition surface 10D of the vapor deposition mask substrate 10. The plating foil 10M formed on the cathode 43 is removed from the cathode 43.

In the electroplating, an electrolytic drum electrode having a mirror-finished surface may be immersed in an electrolytic bath, and another electrode may be placed below the electrolytic drum electrode and face the surface of the electrolytic drum electrode. Passing a current between the electrolytic drum electrode and the other electrode forms plating foil 10M deposited on the electrode surface, which is the surface of the electrolytic drum electrode. The electrolytic drum electrode is rotated until the plating foil 10M obtains a desired thickness, and then the plating foil 10M is peeled off from the front surface of the electrolytic drum electrode and wound.

The electrolytic bath for electroplating contains an iron ion source, a nickel ion source, and a pH buffer. The electrolytic bath for electroplating may also contain a stress relief agent, an Fe³⁺ ion masking agent, and a complexing agent, for example. The electrolytic bath is a weakly acidic solution having a pH adjusted for electrolysis. Examples of the iron ion source include ferrous sulfate heptahydrate, ferrous chloride, and ferrous sulfamate. Examples of the nickel ion source include nickel (II) sulfate, nickel (II) chloride, nickel sulfamate, and nickel bromide. Examples of the pH buffer include boric acid and malonic acid. Malonic acid also functions as an Fe′ ion masking agent. The stress relief agent may be saccharin sodium, for example. The complexing agent may be malic acid or citric acid. The electrolytic bath used for electroplating may be an aqueous solution containing additives listed above and is adjusted using a pH adjusting agent, such as 5% sulfuric acid or nickel carbonate, to have a pH of between 2 and 3 inclusive, for example.

As the conditions for electroplating, the temperature of the electrolytic bath, current density, and electrolysis time are adjusted according to the properties of the plating foil 10M, such as the thickness and composition ratio. The anode used in the electrolytic bath may be a pure iron electrode or a nickel electrode, for example. The cathode used in the electrolytic bath may be a plate of stainless steel such as SUS304. The temperature of the electrolytic bath may be between 40° C. and 60° C. inclusive. The current density may be between 1 A/dm² and 4 A/dm² inclusive. The current density on the surface of the electrode is set to satisfy Condition 1 below. Preferably, the current density at the surface of the electrode is set to satisfy Condition 2, in addition to Condition 1.

[Condition 1] The standard value (MD/T) is less than or equal to 0.05 (mass %/μm).

[Condition 2] The nickel mass proportion is between 35.8 mass % and 42.5 mass % inclusive.

FIG. 8 schematically shows a step of annealing the plating foil 10M.

The plating foil 10M is annealed as shown in FIG. 8. In the annealing step, the plating foil 10M is placed on a mount 52 in an annealing furnace 51. A heating portion 53 heats the plating foil 10M. The annealing steps heats the plating foil 10M to a temperature of 350° C. or higher, preferably 600° C. or higher. The plating foil 10M is heated for one hour, for example. In this step, since the plating foil 10M satisfies Condition 1, the vapor deposition mask substrate 10 obtained through annealing is unlikely to warp upward at the four corners relative to the central section.

[Method for Manufacturing Vapor Deposition Mask]

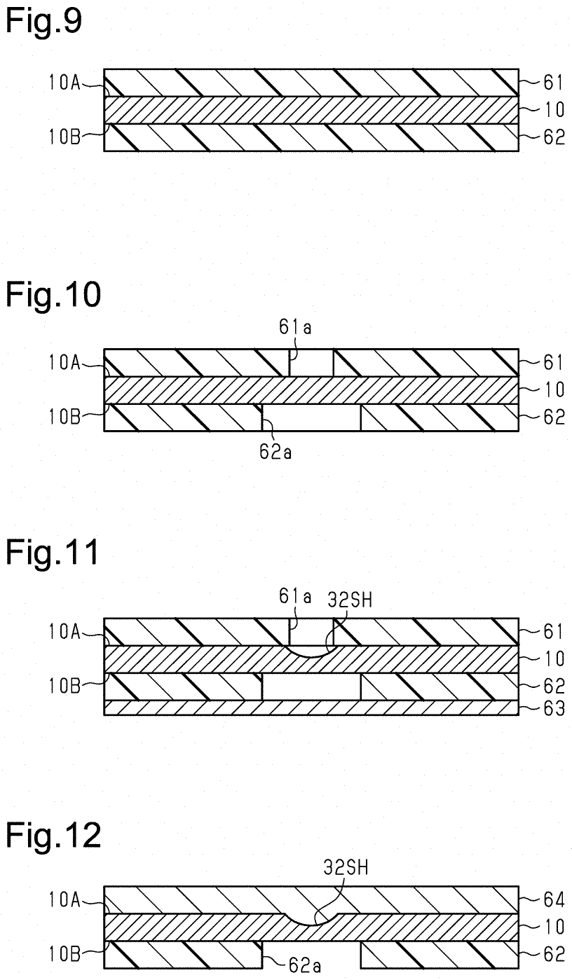

Referring to FIGS. 9 to 17, a method for manufacturing a vapor deposition mask 30 is now described. As the present embodiment of a method for manufacturing a vapor deposition mask 30, steps for manufacturing the mask portion 32 shown in FIG. 4 are described. The process for manufacturing the mask portion 32 shown in FIG. 3 is the same as the process for manufacturing the mask portion 32 shown in FIG. 4 except that the small holes 32SH are formed as through-holes and the step of forming large holes 32LH is omitted. The overlapping steps are not described.

The method for manufacturing the vapor deposition mask 30 includes forming plating foil by electroplating, annealing the plating foil to obtain metal foil, and forming through-holes in the metal foil. Referring to drawings, the method for manufacturing the vapor deposition mask 30 of the present embodiment is now described in detail.

Referring to FIG. 9, manufacturing of mask portions 32 of a vapor deposition mask 30 starts with preparation of a vapor deposition mask substrate 10 including a first surface 10A and a second surface 10B, a first dry film resist (DFR) 61 to be affixed to the first surface 10A, and a second dry film resist (DFR) 62 to be affixed to the second surface 10B. The DFRs 61 and 62 are formed separately from the vapor deposition mask substrate 10. Then, the first DFR 61 is affixed to the first surface 10A, and the second DFR 62 is affixed to the second surface 10B.

Referring to FIG. 10, the sections of the DFRs 61 and 62 other than the sections in which holes are to be formed are exposed to light, and then the DFRs 61 and 62 are developed. This forms first through-holes 61a in the first DFR 61 and second through-holes 62a in the second DFR 62. The development of the exposed DFRs uses sodium carbonate solution, for example, as the developing solution.

As shown in FIG. 11, the first surface 10A of the vapor deposition mask substrate 10 may be etched with ferric chloride solution using the developed first DFR 61 as the mask. Here, a second protection layer 63 is formed on the second surface 10B so that the second surface 10B is not etched together with the first surface 10A. The second protection layer 63 is made of a material that chemically resists the ferric chloride solution. Small holes 32SH extending toward the second surface 10B are thus formed in the first surface 10A. Each small hole 32SH includes a first opening H1, which opens at the first surface 10A.

The etchant for etching the vapor deposition mask substrate 10 is not limited to ferric chloride solution, and may be an acidic etchant that is capable of etching an iron-nickel alloy. The acidic etchant may be a solution containing perchloric acid, hydrochloric acid, sulfuric acid, formic acid, or acetic acid mixed in a ferric perchlorate solution or a mixture of a ferric perchlorate solution and a ferric chloride solution. The vapor deposition mask substrate 10 may be etched by a dipping method that immerses the vapor deposition mask substrate 10 in an acidic etchant, or by a spraying method that sprays an acidic etchant onto the vapor deposition mask substrate 10.

Referring to FIG. 12, the first DFR 61 formed on the first surface 10A and the second protection layer 63 on the second DFR 62 are removed. In addition, a first protection layer 64 is formed on the first surface 10A to prevent additional etching of the first surface 10A. The first protection layer 64 is made of a material that chemically resists the ferric chloride solution.

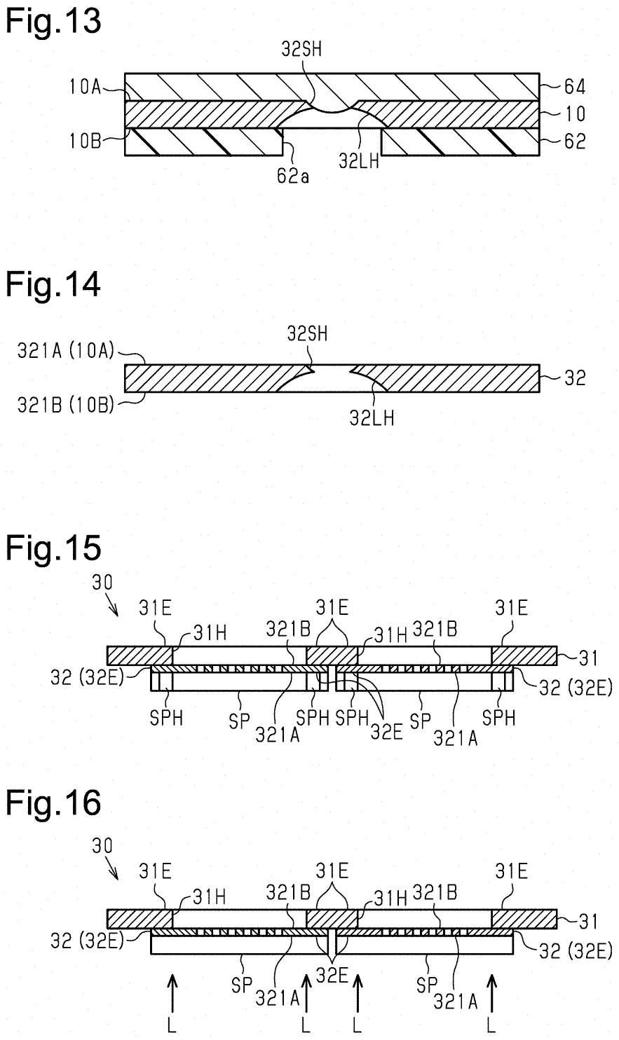

As shown in FIG. 13, the second surface 10B is etched with ferric chloride solution using the developed second DFR 62 as the mask. Large holes 32LH extending toward the first surface 10A are thus formed in the second surface 10B. Each large hole 32LH has a second opening H2, which opens at the second surface 10B. The second openings H2 are larger than the first openings H1 in a plan view of the second surface 10B. The etchant used in this step may also be any acidic etchant capable of etching the iron-nickel alloy. The vapor deposition mask substrate 10 may be etched by a dipping method that immerses the vapor deposition mask substrate 10 in an acidic etchant, or by a spraying method that sprays an acidic etchant onto the vapor deposition mask substrate 10.

As shown in FIG. 14, removing the first protection layer 64 and the second DFR 62 from the vapor deposition mask substrate 10 provides the mask portion 32 having small holes 32SH and large holes 32LH connected to the small holes 32SH.

In the manufacturing method using rolling, the vapor deposition mask substrate includes some amount of a metallic oxide, such as an aluminum oxide or a magnesium oxide. That is, when the base material is formed, a deoxidizer, such as granular aluminum or magnesium, is typically mixed into the material to limit mixing of oxygen into the base material. The aluminum or magnesium remains to some extent in the base material as a metallic oxide such as an aluminum oxide or a magnesium oxide. In this respect, the method for manufacturing a vapor deposition mask substrate using electroplating limits mixing of the metallic oxide into the mask portion 32.

The mask portion 32 thus formed is joined to the frame portion 31 by any one of the three methods described below with reference to FIGS. 15 to 17, so that the vapor deposition mask 30 is obtained. Before the joining step to be described referring to FIGS. 15 to 17, a support may be affixed to the first surface 321A of the mask portion 32. This support limits warpage of the mask portion 32 in the joining step, allowing the mask portion 32 to be joined to the frame portion 31 in a stable manner.

The support does not have to be affixed to the mask portion 32 when the warpage of the mask portion 32 is small. Further, when the mask portion 32 has the structure described above with reference to FIG. 3, the support may be affixed to the vapor deposition mask substrate 10 before the etching of the vapor deposition mask substrate 10.

The example shown in FIG. 15 uses resistance welding to join the outer edge sections 32E of the second surface 321B to the inner edge sections 31E of the frame portion 31. This method forms holes SPH in an insulative support SP. The holes SPH are formed in the sections of the support SP that face the sections that become joining sections 32BN described above with reference to FIG. 5. Then, energization through the holes SPH is performed to form the joining sections 32BN intermittently. This welds the outer edge sections 32E to the inner edge sections 31E. The support SP is then peeled off from the mask portion 32, leaving the vapor deposition mask 30.

The example shown in FIG. 16 uses laser welding to join the outer edge sections 32E of the second surface 321B to the inner edge sections 31E of the frame portion 31. This method uses a light transmitting support SP and irradiates the sections that become joining sections 32BN with laser light L through the support SP. Separate joining sections 32BN are formed by intermittently applying laser light L around the outer edge section 32E. Alternatively, a continuous joining section 32BN is formed along the entire circumference of the outer edge section 32E by continuously applying laser light L around the outer edge sections 32E. This welds the outer edge sections 32E to the inner edge sections 31E. The support SP is then peeled off from the mask portion 32, leaving the vapor deposition mask 30.

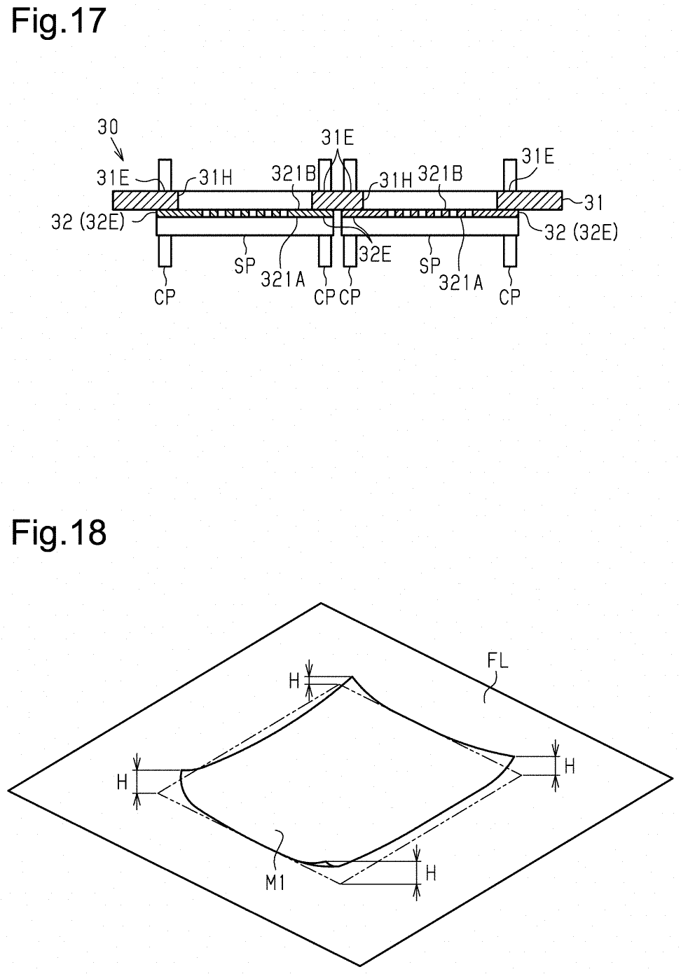

The example shown in FIG. 17 uses ultrasonic welding to join the outer edge sections 32E of the second surface 321B to the inner edge sections 31E of the frame portion 31. This method applies ultrasonic waves to the sections that become joining sections 32BN with the outer edge sections 32E and the inner edge sections 31E held together by clamps CP or other device. The member to which ultrasonic waves are directly applied may be the frame portion 31 or the mask portion 32. The method using ultrasonic welding leaves crimp marks of the clamps CP in the frame portion 31 and the support SP. The support SP is then peeled off from the mask portion 32, leaving the vapor deposition mask 30.

In the joining process described above, fusing or welding may be performed while stress is acting on the mask portion 32 outward of the mask portion 32. When the support SP supports the mask portion 32 while stress is acting on the mask portion 32 outward of the mask portion 32, the application of stress to the mask portion 32 may be omitted.

In the example described referring to FIGS. 15 to 17, the second surface 321B of the mask portion 32 is joined to the frame portion 31, but the first surface 321A of the mask portion 32 may be joined to the frame portion 31.

[Method for Manufacturing Display Device]

In the method for manufacturing a display device using the vapor deposition mask 30 described above, the mask device 20 to which the vapor deposition mask 30 is mounted is set in the vacuum chamber of the vapor deposition apparatus. The mask device 20 is attached such that the first surface 321A faces the vapor deposition target, such as a glass substrate, and the second surface 321B faces the vapor deposition source. Then, the vapor deposition target is transferred into the vacuum chamber of the vapor deposition apparatus, and the vapor deposition material is sublimated from the vapor deposition source. This forms a pattern that is shaped corresponding to the first opening H1 on the vapor deposition target, which faces the first opening H1. The vapor deposition material may be an organic light-emitting material for forming pixels of a display device, or the material of a pixel electrode for forming a pixel circuit of a display device, for example.

### Examples

Referring to FIGS. 18 to 24, examples are now described.

To form plating foil by electroplating to obtain a vapor deposition mask substrate of each of Examples 1 to 8 and Comparison Examples 1 to 7, an aqueous solution including the additives listed below was used as the electrolytic bath. The electrolytic bath had a pH of 2.3. The plating foil of each of Examples 1 to 8 and Comparison Examples 1 to 7 was obtained by varying the current density in the range of 1 (A/dm²) to 4 (A/dm²) in electroplating. Pieces of plating foil each having a length of 150 mm and a width of 150 mm were thus obtained.

[Electrolytic Bath]

Ferrous sulfate heptahydrate: 83.4 g/L

Nickel(II) sulfate hexahydrate: 250.0 g/L

Nickel(II) chloride hexahydrate: 40.0 g/L

Boric acid: 30.0 g/L

Saccharin sodium dihydrate: 2.0 g/L

Malonic acid: 5.2 g/L

Temperature: 50° C.

From the plating foil formed by electroplating, a square first metal piece having a length of 50 mm and a width of 50 mm was cut out. The first metal piece was cut out from the plating foil such that each side of the first metal piece was parallel to the corresponding side of the plating foil and that the center of the first metal piece substantially coincided with the center of the plating foil. The first metal piece was then heated in a vacuum with the heating temperature set to 600° C. and the heating time set to one hour. The first metal piece of each example and comparison example was thus obtained. As will be described below, the first metal piece was used as the object of the measurement of the curl amount.

In addition, from each piece of plating foil, a square second metal piece having a length of 10 mm and a width of 10 mm was cut out from an area near the region where the first metal piece was cut out. As will be described below, the second metal pieces were used as the objects of measurement of the thickness, the composition ratio at the electrode surface, and the composition ratio at the deposition surface.

The second metal piece of each example and comparison example was measured for the thickness, the composition ratio at the electrode surface, and the composition ratio at the deposition surface. The thickness was measured using a scanning electron microscope (SEM) (JSM-7001F, manufactured by JEOL Ltd.). The composition ratio was measured using an energy dispersive X-ray analyzer (EDX) (INCA PentaFET×3, manufactured by Oxford Instruments) mounted on the SEM. The composition ratio at the cross-sections of the second metal pieces was measured at a magnification of 5000×. The accelerating voltage of the SEM was set to 20 kV, and secondary electron images were obtained. The measurement time of EDX was set to 60 seconds.

A cross-section of the second metal piece of each example and comparison example was exposed using a cross section polisher. The composition ratio measured at a cross-section 0.5 μm inside the electrode surface (10E) was defined as the composition ratio at the electrode surface, and the composition ratio measured at a cross-section 0.5 μm inside the deposition surface (10D) was defined as the composition ratio at the deposition surface. For each surface, the composition ratio was measured at three different positions, and the average value of the values measured at these three points was used as the composition ratio at each surface. The absolute value of the difference between the mass proportion of Ni at the deposition surface (the second nickel mass proportion) (mass %) and the mass proportion of Ni at the electrode surface (the first nickel mass proportion) (mass %) was calculated as a mass difference (MD) (mass %). The standard value (MD/T) (mass %/μm) was obtained by dividing the mass difference (MD) (mass %) by the thickness (T) (μm) of the vapor deposition mask substrate.

As shown in FIG. 18, the first metal piece M1 of each example and comparison example was placed on a flat surface FL such that the four corners of the first metal piece M1 were warped away from the flat surface FL, in other words, warped upward from the flat surface FL. At each of the four corners of the first metal piece M1, the height H (mm), which is the distance between the flat surface and the corner, was measured, and the average value of the heights H at the four corners was calculated as a curl amount (mm).

The linear expansion coefficient of the first metal piece of each example and comparison example was measured by a thermomechanical analysis (TMA) technique. A thermomechanical analyzer (TMA-50, manufactured by Shimadzu Corporation) was used to measure the linear expansion coefficient. The average value of the linear expansion coefficients measured at the range of between 25° C. and 100° C. inclusive was obtained as a linear expansion coefficient.

[Analysis Results]

Table 1 shows the thickness (T), the mass proportion of Ni at the deposition surface (the second nickel mass proportion), the mass proportion of Ni at the electrode surface (the first nickel mass proportion), the mass difference (MD), the standard value (MD/T), the curl amount, and the linear expansion coefficient of each example and comparison example.

| | | Deposition | Electrode | Mass | Standard | | Linear |
|---|---|---|---|---|---|---|---|
| | Thickness | surface | surface | difference | value | Curl | expansion |
| | T | 10D | 10E | MD | MD/T | amount | coefficient |
| | (μm) | (mass %) | (mass %) | (mass %) | (mass %/μm) | (mm) | (10⁻⁶/° C.) |
| Example 1 | 3 | 36.4 | 36.3 | 0.1 | 0.030 | 0.2 | 2.1 |
| Example 2 | 5 | 36.5 | 36.3 | 0.2 | 0.040 | 0.4 | 2.1 |
| Example 3 | 7 | 36.6 | 36.3 | 0.3 | 0.040 | 0.5 | 2.1 |
| Example 4 | 10 | 35.8 | 36.0 | 0.2 | 0.020 | 0.0 | 2.0 |
| Example 5 | 10 | 42.4 | 42.5 | 0.1 | 0.010 | 0.0 | 4.0 |
| Example 6 | 10 | 36.5 | 36.0 | 0.5 | 0.050 | 0.3 | 2.1 |
| Example 7 | 15 | 42.1 | 42.2 | 0.1 | 0.007 | 0.0 | 4.0 |
| Example 8 | 15 | 36.2 | 36.8 | 0.6 | 0.040 | 0.6 | 2.1 |
| Comparison | 7 | 36.3 | 37.1 | 0.8 | 0.110 | 7.5 | 2.2 |
| Example 1 | | | | | | | |
| Comparison | 15 | 36.9 | 41.7 | 4.8 | 0.320 | — | 2.5 |
| Example 2 | | | | | | | |
| Comparison | 15 | 43.1 | 45.5 | 2.4 | 0.160 | 16.3 | 4.4 |
| Example 3 | | | | | | | |
| Comparison | 15 | 41.6 | 43.3 | 1.7 | 0.110 | 13.0 | 4.1 |
| Example 4 | | | | | | | |
| Comparison | 10 | 40.1 | 40.9 | 0.8 | 0.080 | 5.2 | 3.5 |
| Example 5 | | | | | | | |
| Comparison | 10 | 36.0 | 36.7 | 0.7 | 0.070 | 2.3 | 2.1 |
| Example 6 | | | | | | | |
| Comparison | 15 | 36.4 | 37.5 | 1.1 | 0.073 | 6.5 | 2.2 |
| Example 7 | | | | | | | |

As shown in Table 1, the second metal piece of each example had a mass difference (MD) of less than or equal to 0.6 mass % and a standard value (MD/T) of less than or equal to 0.05 (mass %/μm). The first metal piece of each example had a curl amount of less than or equal to 0.6 mm. In contrast, the second metal piece of each comparison example had a mass difference (MD) of greater than or equal to 0.7 mass % and a standard value (MD/T) of greater than or equal to 0.07 (mass %/μm). The first metal piece of each comparison example had a curl amount of greater than or equal to 2.3 mm. The first metal piece of Comparison Example 2 assumed a tubular shape, and it was thus impossible to measure its curl amount. In addition, with the first metal pieces having a curl amount of greater than 0.0 mm, it was observed that each first metal piece was warped upward in the direction from the surface with a lower Ni mass proportion to the surface with a higher Ni mass proportion.

The results of the measurement of the composition ratio at each surface showed that the remainder other than nickel in each second metal piece was substantially entirely iron. Further, in each example and comparison example, the composition ratio before annealing and the composition ratio after annealing were the same.

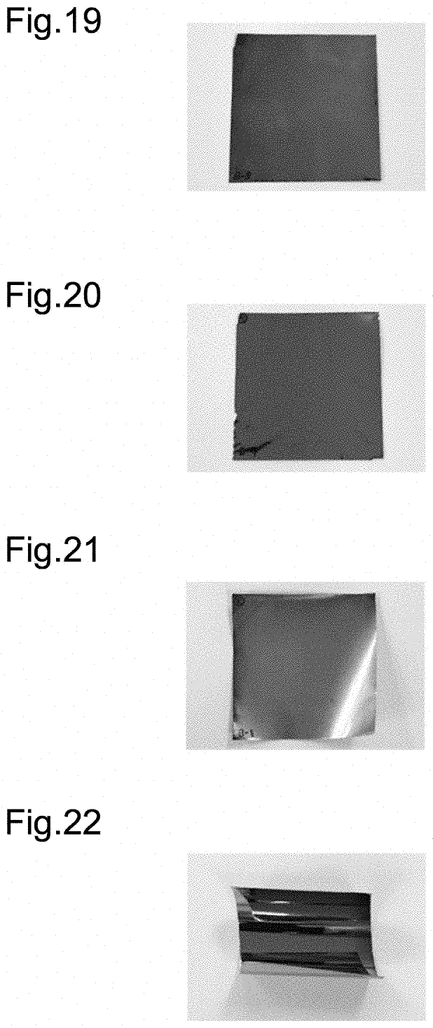

FIG. 19 is a photograph of the first metal piece of Example 5, and FIG. 20 is a photograph of the first metal piece of Example 6. As shown in FIGS. 19 and 20, the first metal pieces were substantially flat when the curl amount was about 0.3 mm. That is, each first metal piece was observed to have a shape that substantially extended along the flat surface FL. FIG. 21 is a photograph of the first metal piece of Comparison Example 5, and FIG. 22 is a photograph of the first metal piece of Comparison Example 3. As shown in FIG. 21, when the curl amount exceeded 5 mm, the four corners of the first metal piece were significantly warped upward. Further, as shown in FIG. 22, when the curl amount exceeded 15 mm, the four corners of the first metal piece were warped upward more prominently. For each of the examples and comparison examples, the metal foil was substantially flat before annealing.

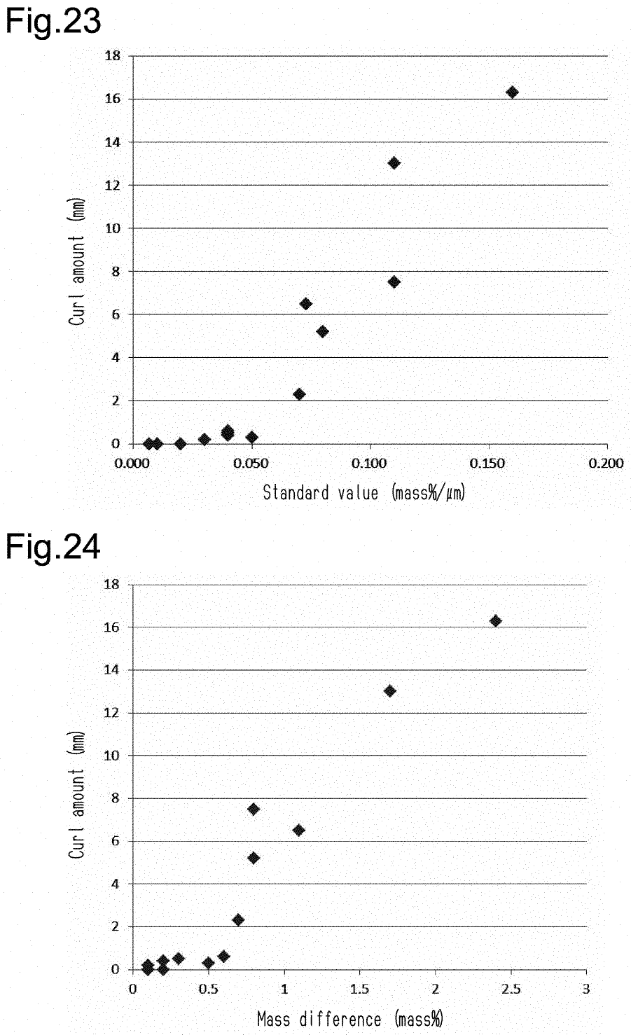

FIG. 23 shows the relationship between the standard value (MD/T) and the curl amount.

As shown in FIG. 23, when the standard value (MD/T) (mass %/μm), which is the value obtained by dividing the mass difference (MD) (mass %) by the thickness (T) of the second metal piece, exceeded 0.05 (mass %/μm), the curl amount of the first metal piece was significantly larger than those in pieces with a standard value (MD/T) of less than or equal to 0.05 (mass %/μm).

FIG. 24 shows the relationship between the mass difference (MD) and the curl amount.

As shown in FIG. 24, when the mass difference (MD) (mass %) exceeded 0.6 (mass %), the curl amount of the first metal piece was significantly larger than those in pieces with a mass difference (MD) of less than or equal to 0.6 (mass %).

As described above, embodiments of a vapor deposition mask substrate, a method for manufacturing a vapor deposition mask substrate, a method for manufacturing a vapor deposition mask, and a method for manufacturing a display device have the following advantages.

(1) The standard value (MD/T), which is the amount of change in the mass proportion of Ni per unit thickness of the vapor deposition mask substrate 10, is less than or equal to 0.05 (mass %/μm), thereby limiting upward warpage at the four corners of the vapor deposition mask substrate 10 relative to the central section.

(2) The mass difference (MD) is less than or equal to 0.6 (mass %), thereby limiting upward warpage at the four corners of the vapor deposition mask substrate 10 relative to the central section.

(3) The vapor deposition mask 30 can have holes having a depth of less than or equal to 15 μm, so that the volume of holes in the vapor deposition mask 30 is small. This reduces the amount of vapor deposition material that adheres to the vapor deposition mask 30 when passing through the holes in the vapor deposition mask 30.

(4) The embodiment allows for a smaller difference in linear expansion coefficient between the vapor deposition mask substrate 10 and a glass substrate, and a smaller difference in linear expansion coefficient between the vapor deposition mask substrate 10 and a polyimide sheet. Consequently, the change in size of the vapor deposition mask caused by thermal expansion will be equivalent to the change in size of a glass substrate and a polyimide sheet caused by thermal expansion. Thus, when the vapor deposition target is a glass substrate or a polyimide sheet, the vapor deposition mask forms the vapor deposition pattern with an increased accuracy.

The above-described embodiments may be modified as follows.

### [Thickness]

The thickness of the vapor deposition mask substrate 10 may be greater than 15 μm.

### [Etching]

In the etching of the vapor deposition mask substrate 10, large holes 32LH opening at the first surface 10A of the vapor deposition mask substrate 10 and small holes 32SH opening at the second surface 10B may be formed.

### DESCRIPTION OF THE REFERENCE NUMERALS

10 . . . Vapor Deposition Mask Substrate; 10A, 321A . . . First Surface; 10B, 321B . . . Second Surface; 10D . . . Deposition Surface; 10E . . . Electrode Surface; 10M . . . Plating foil; 20 . . . Mask Device; 21 . . . Main Frame; 21H . . . Main Frame Hole; 30 . . . Vapor Deposition Mask; 31 . . . Frame Portion; 31A . . . Joining Surface; 31B . . . Nonjoining Surface; 31E . . . Inner Edge Section; 31H . . . Frame Hole; 31HA . . . First Frame Hole; 31HB . . . Second Frame Hole; 31HC . . . Third Frame Hole; 32 . . . Mask Portion; 32A . . . First Mask Portion; 32B . . . Second Mask Portion; 32C . . . Third Mask Portion; 32BN . . . Joining Section; 32E . . . Outer Edge Section; 32H, SPH . . . Hole; 32LH . . . Large Hole; 32SH . . . Small Hole; 41 . . . Electrolytic Chamber; 42 . . . Electrolytic Bath; 43 . . . Cathode; 44 . . . Anode; 45 . . . Power Source; 51 . . . Annealing Furnace; 52 . . . Mount; 53 . . . Heating Portion; 61 . . . First Dry Film Resist; 61a . . . First Through-Hole; 62 . . . Second Dry Film Resist; 62a . . . Second Through-Hole; 63 . . . Second Protection Layer; 64 . . . First Protection Layer; 321 . . . Mask Plate; CP . . . Clamp; FL . . . Flat Surface; H . . . Height; H1 . . . First Opening; H2 . . . Second Opening; L . . . Laser Light; M1 . . . First Metal Piece; S . . . Vapor Deposition Target; SH . . . Step Height; SP . . . Support; V . . . Space

1. A vapor deposition mask substrate, which is metal foil formed by electroplating, wherein
the metal foil is made of an iron-nickel alloy,
the metal foil includes
a first surface, and
a second surface opposite to the first surface,
the first surface has a first nickel mass proportion (mass %), which is a percentage of a mass of nickel in a sum of a mass of iron and the mass of nickel at the first surface,
the second surface has a second nickel mass proportion (mass %), which is a percentage of a mass of nickel in a sum of a mass of iron and the mass of nickel at the second surface,
an absolute value of a difference between the first nickel mass proportion (mass %) and the second nickel mass proportion (mass %) is a mass difference (mass %),
a value obtained by dividing the mass difference by a thickness (μm) of the vapor deposition mask substrate is a standard value, and
the standard value is less than or equal to 0.05 (mass %/μm).

2. The vapor deposition mask substrate according to claim 1, wherein the vapor deposition mask substrate has a thickness of less than or equal to 15 μm.

3. The vapor deposition mask substrate according to any one of claim 1, wherein each of the first nickel mass proportion and the second nickel mass proportion is between 35.8 mass % and 42.5 mass % inclusive.

4. A vapor deposition mask substrate, which is metal foil formed by electroplating, wherein
the metal foil is made of an iron-nickel alloy,
the metal foil includes
a first surface, and
a second surface opposite to the first surface,
the first surface has a first nickel mass proportion (mass %), which is a percentage of a mass of nickel in a sum of a mass of iron and the mass of nickel at the first surface,
the second surface has a second nickel mass proportion (mass %), which is a percentage of a mass of nickel in a sum of a mass of iron and the mass of nickel at the second surface,
an absolute value of a difference between the first nickel mass proportion (mass %) and the second nickel mass proportion (mass %) is a mass difference (mass %), and
the mass difference is less than or equal to 0.6 (mass %).

5. The vapor deposition mask substrate according to claim 4, wherein the vapor deposition mask substrate has a thickness of less than or equal to 15 μm.

6. The vapor deposition mask substrate according to any one of claim 4, wherein each of the first nickel mass proportion and the second nickel mass proportion is between 35.8 mass % and 42.5 mass % inclusive.

7. A method for manufacturing a vapor deposition mask substrate, which is metal foil formed by electroplating, the method comprising:
forming plating foil by the electroplating; and
annealing the plating foil to obtain the metal foil, wherein
the metal foil is made of an iron-nickel alloy,
the metal foil includes
a first surface, and
a second surface opposite to the first surface,
the first surface has a first nickel mass proportion (mass %), which is a percentage of a mass of nickel in a sum of a mass of iron and the mass of nickel at the first surface,
the second surface has a second nickel mass proportion (mass %), which is a percentage of a mass of nickel in a sum of a mass of iron and the mass of nickel at the second surface,
an absolute value of a difference between the first nickel mass proportion (mass %) and the second nickel mass proportion (mass %) is a mass difference (mass %),
a value obtained by dividing the mass difference by a thickness (μm) of the vapor deposition mask substrate is a standard value, and
the standard value is less than or equal to 0.05 (mass %/μm).
